(19) United States
(12) Patent Application Publication
(10) Pub. No.: US 2008/0239267 A1
(43) Pub. Date: Oct. 2, 2008

(54) Exposure apparatus and exposure method for exposure apparatus

(75) Inventors: Issei Suzuki, Odawara-shi (JP); Taishi Teraji, Ebina-shi (JP); Hirofumi Saita, Minami-ashigara-shi (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: FUJIFILM CORPORATION, Tokyo (JP)

(21) Appl. No.: 12/068,821

(22) Filed: Feb. 12, 2008

(30) Foreign Application Priority Data
Mar. 30, 2007 (JP) 2007-093365

(51) Int. Cl. G03B 27/42; G03F 7/20

(52) U.S. Cl. 355/53; 430/30

(57) ABSTRACT

Post-etching line width localities that occur due to resist film thickness localities can be corrected continuously, without the need for an expensive mask. After a resist applied to a thin film on a substrate is scanned and exposed by an exposure machine, which is selectively turned on and off by image data, the resist and the thin film are developed and etched to produce a pattern having a desired line width. Before the resist is exposed, a film thickness of the resist on the substrate is measured at each of plural locations on the substrate. The measured film thickness is reflected in a predetermined relationship between a pre-exposure film thickness of the resist and a post-etching corrective line width, for thereby determining a corrective line width amount at each of the plural locations on the substrate.

### BACKGROUND OF THE INVENTION

1. Field of the Invention

The present invention relates to an exposure apparatus as well as to an exposure method to be carried out by the exposure apparatus for scanning and exposing a resist applied to a thin film on a substrate with an exposure machine, which is selectively turned on and off under the control of image data, and thereafter developing and etching the resist to produce a pattern having a desired line width in the thin film.

2. Description of the Related Art

According to a process for fabricating semiconductor or FPD (Flat Panel Display) circuits, a circuit pattern is generated by photolithography, as shown in FIG. 13 of the accompanying drawings.

Specifically, a base thin film 2 to be patterned is grown on a substrate (referred to as a “wafer” in the case of semiconductor circuits and a “glass substrate” in the case of FPD circuits) 1, and then a photosensitive resist 3 is deposited as a uniform resist coating film, having a thickness of several microns, on the base thin film 2 by spin coating or by using a slit coater (resist applying step).

Thereafter, the resist 3 is dried and solidified by prebaking (prebaking step). The entire assembly, including the substrate 1 with the resist 3 applied to the thin film 2 thereof at the time it is prebaked, is referred to as a “substrate F”.

Then, the substrate F is exposed to light having a two-dimensional pattern in an exposure machine (exposure step), thereby producing a latent image on the resist 3.

Then, the substrate F is developed to remove unwanted regions of the resist 3 therefrom (developing step). The substrate F is postbaked, to hold the resist 3 and the substrate 1 in closer adhesion with each other, to thereby provide a resist pattern that can be used as an etching mask.

Finally, the thin film 2 is dissolved away by an etching solution (wet etching), or the thin film 2 is scraped away by a plasma (etching particles) (dry etching), thus providing a thin film pattern (etching step). The resist 3 is then peeled off by a peeling solution (peeling step) in order to produce a two-dimensional pattern having a desired line width on the substrate 1.

In the etching step, the line width of the pattern etched in the thin film 2 is affected not only by the line width of the resist 3, but also by the profile (remaining film quantity and taper angle) of the resist 3, because the etching particles progressively scrape away unwanted regions of the resist 3 as it is etched.

FIG. 14A of the accompanying drawings shows in cross section (on the right) a resist profile of the resist 3 where the taper angle θ is large, and (on the left) a resist profile of the resist 3 where the taper angle θ is small, before the thin film 2 is etched.

FIG. 14B of the accompanying drawings shows in cross section (on the right) a resist profile of the resist 3 where the taper angle θ is large and (on the left) a resist profile of the resist 3 where the taper angle θ is small, after the thin film 2 has been etched. When the taper angle θ is large, the line width L1 of the resist 3 and the line width L2 of the etched thin film 2 are substantially equal to each other (L2≈L1). By contrast, when the taper angle θ is small, the line width L3 of the etched thin film 2 is smaller than the line width L1 of the resist 3 (L3<L1), which indicates that the pattern produced on the substrate 1 has a smaller line width.

In the resist applying step, the resist 3 may not be applied with a uniform thickness over the entire surface of the substrate 1, due to surface undulations of the substrate 1 as well as different resist viscosity levels that occur on the central and peripheral regions of the substrate 1 upon spin coating. Therefore, the resist 3 may suffer from different localized film thicknesses, resulting in an irregular distribution of the resist film thickness at different locations on the substrate 1.

The resist 3 also is subject to fixed different film thickness localities, due to deformations in the substrate 1 when it is supported by a pin. Since mother substrates have recently become larger in size, it is more difficult to maintain a uniform resist coating thickness, thus posing problems of film thickness locality on the resist 3.

FIG. 15 of the accompanying drawings is a diagram showing the relationship of taper angle θ [deg] and resist sensitivity E0 [mJ/cm²] to the resist film thickness t [μm], as measured by the inventor of the present application.

From FIG. 15, it can be seen that the resist sensitivity E0 and the taper angle θ differ depending on different values of the resist film thickness t.

Different values of the resist sensitivity E0, different values of the taper angle θ, and different values of the resist film thickness t, all lead to differing line widths in the final pattern, which is produced after the thin film has been etched, ultimately resulting in display luminance irregularities, due to different light transmittance values in the pixels of FPDs, such as LCDs or the like.

A proposed solution to the above problems is disclosed in Japanese Laid-Open Patent Publication No. 7-029810.

According to the method disclosed in Japanese Laid-Open Patent Publication No. 7-029810, an exposure apparatus produces a pattern by projecting a mask pattern through a projecting optical system onto a substrate coated with a resist, and sequentially scanning the mask and the substrate. An exposure amount setting means determines an adequate amount of exposure f(x), according to the film thickness distribution of the resist on the substrate. An exposure amount adjusting means then adjusts an illuminance level L(x) per shot, in order to satisfy the adequate amount of exposure f(x) at each position x, for thereby correcting resolution failures and line width.

According to the disclosed method, since the amount of exposure is adjusted per shot, the line width tends to vary at junctions between shots. It is necessary to change expensive masks for correcting line widths, based on techniques other than the amount of exposure, and also to correct line widths in the input image data.

A digital exposure apparatus also has been proposed for exposing a resist to a wiring pattern, without the need for an expensive mask, as disclosed in Japanese Laid-Open Patent Publication No. 2005-266779. The disclosed digital exposure apparatus employs a spatial optical modulator, such as a digital micromirror device (DMD), for scanning and exposing the resist. The DMD comprises a number of micromirrors, which are tiltably disposed in a grid-like array on SRAM cells (memory cells). The micromirrors have respective surfaces with a highly reflective material, such as aluminum or the like, evaporated thereon. When a digital signal representative of image data is written into the SRAM cells, the corresponding micromirrors are tilted in a given direction depending on the digital signal, thereby selectively turning on and off light beams while directing the turned-on light beams toward the resist, to record a wiring pattern on the resist.

However, such a digital exposure apparatus has not incorporated any technique for correcting post-etching line width localities (i.e., irregular distribution of line widths at different locations on the substrate), which occur due to different resist film thickness localities.

### SUMMARY OF THE INVENTION

An object of the present invention is to provide an exposure apparatus, as well as an exposure method carried out in the exposure apparatus, which are capable of correcting post-etching line width localities that occur due to different resist film thickness localities.

According to the present invention, there is provided an exposure method to be performed by an exposure apparatus, for scanning and exposing a resist applied to a thin film on a substrate utilizing an exposure machine that is selectively turned on and off by image data, and thereafter developing and etching the resist and the thin film so as to produce a pattern having a desired line width in the thin film, the exposure method comprising the steps of measuring a pre-exposure film thickness of the resist on the substrate, determining a corrective etching line width amount for the measured pre-exposure film thickness of the resist, based on a predetermined relationship between the pre-exposure film thickness of the resist and the post-etching corrective line width, and correcting the pattern so as to achieve the desired line width, based on the determined post-etching corrective line width amount.

Since the corrective etching line width amount for the measured pre-exposure film thickness of the resist is determined based on the predetermined relationship between the pre-exposure film thickness of the resist and the post-etching corrective line width, and since the pattern is corrected to achieve a desired line width based on the determined post-etching corrective line width amount, the desired line width can be achieved by means of a simple process.

The step of correcting the pattern comprises a step of correcting an amount of exposure set in the exposure machine, depending on a location on the substrate.

Since the amount of exposure set in the exposure machine is corrected depending on the location on the substrate, a mask is not required, and the utilized exposure machine can be inexpensive.

The exposure machine comprises an exposure head having a plurality of exposure recording elements therein. The exposure amount set in the exposure machine is corrected by turning off selected ones of the exposure recording elements.

The exposure machine can be controlled with ease, since only selected ones of the exposure recording elements are turned off.

The exposure machine comprises a plurality of exposure heads.

The exposure machine comprises a digital micromirror device that includes the exposure recording elements, and an illuminating system for applying illuminating light to the digital micromirror device.

The exposure machine comprises a light deflector, wherein the step of correcting the exposure amount set in the exposure machine further comprises a step of correcting an intensity of a light beam, which is deflected by the light deflector depending on the location on the substrate. The light deflector may comprise a rotary polygon mirror, a galvanometer mirror, or the like.

The step of correcting the pattern further comprises a step of correcting the image data depending on a location on the substrate, so as to correct an exposure amount set in the exposure machine.

Since the image data are corrected, the pattern can easily be corrected.

The step of correcting the image data further comprises a step of enlarging or reducing the line width, depending on the location on the substrate.

According to the present invention, there is also provided an exposure apparatus for scanning and exposing a resist applied to a thin film on a substrate utilizing an exposure machine that is selectively turned on and off by image data, and thereafter developing and etching the resist and the thin film so as to produce a pattern having a desired line width in the thin film, the exposure apparatus comprising a film thickness measuring unit for measuring a pre-exposure film thickness of the resist on the substrate, corrective line width amount determining means for determining a corrective etching line width amount for the measured pre-exposure film thickness of the resist, based on a predetermined relationship between the pre-exposure film thickness of the resist and the post-etching corrective line width, and an amount-of-exposure correcting means for correcting an amount of exposure set in the exposure machine so as to achieve the desired line width, based on the determined post-etching corrective line width amount.

Since the corrective etching line width amount for the measured pre-exposure film thickness of the resist is determined based on the predetermined relationship between the pre-exposure film thickness of the resist and the post-etching corrective line width, and further since the exposure amount set in the exposure machine is corrected to achieve a desired line width based on the determined post-etching corrective line width amount, the exposure amount set in the exposure machine can be corrected in order to achieve a desired line width according to a simple process.

According to the present invention, post-etching line width localities that occur due to resist film thickness localities can be corrected with a simple arrangement.

The post-etching line width localities can be corrected continuously, but not shot-by-shot (step-by-step) as in Japanese Laid-Open Patent Publication No. 7-029810. Therefore, the line width can be corrected smoothly, even at junctions between shots. If the exposure method is applied to the fabrication of an LCD, then illuminance irregularities in the LCD are reduced. Since a mask is not required, the exposure machine is inexpensive. Inasmuch as post-etching line width localities can be corrected in one scanning and exposing cycle, not shot-by-shot (step-by-step), the time required to correct post-etching line width localities is relatively short.

The above and other objects, features, and advantages of the present invention will become more apparent from the following description when taken in conjunction with the accompanying drawings in which preferred embodiments of the present invention are shown by way of illustrative example.

### BRIEF DESCRIPTION OF THE DRAWINGS

FIG. 1 is a perspective view of an exposure apparatus according to an embodiment of the present invention;

FIG. 2 is a schematic view of an exposure head of the exposure apparatus shown in FIG. 1;

FIG. 3 is an enlarged fragmentary perspective view showing a DMD employed in the exposure head shown in FIG. 2;

FIG. 4 is a view illustrating an exposure recording process performed by the exposure head shown in FIG. 2;

FIG. 5 is a diagram showing the DMD of the exposure head shown in FIG. 2, along with mask data set in the DMD;

FIG. 6 is a diagram showing the relationship between recording positions and amount-of-light localities, in the exposure apparatus according to the present embodiment;

FIG. 7 is a diagram showing line widths recorded when the amount-of-light localities shown in FIG. 6 are left uncorrected;

FIG. 8 is a diagram showing a line width recorded when the amount-of-light localities shown in FIG. 6 are corrected;

FIG. 9 is a block diagram of a control circuit of the exposure apparatus according to the present embodiment;

FIG. 10 is a flowchart indicating an operation sequence of the control circuit shown in FIG. 9;

FIG. 11 is a block diagram of a control circuit according to another embodiment of the present invention;

FIG. 12 is a flowchart indicating an operation sequence of the control circuit shown in FIG. 11;

FIG. 13 is a view illustrating a process for fabricating semiconductor or FPD circuits;

FIG. 14A is a cross-sectional view showing a resist profile in which the taper angle of a resist is large, together with a resist profile in which the taper angle of the resist is small, before a thin film is etched;

FIG. 14B is a cross-sectional view showing a resist profile in which the taper angle of a resist is large, together with a resist profile where the taper angle of the resist is small, after a thin film is etched; and

FIG. 15 is a graph showing a relationship of the taper angle and resist sensitivity to the resist film thickness.

### DESCRIPTION OF THE PREFERRED EMBODIMENTS

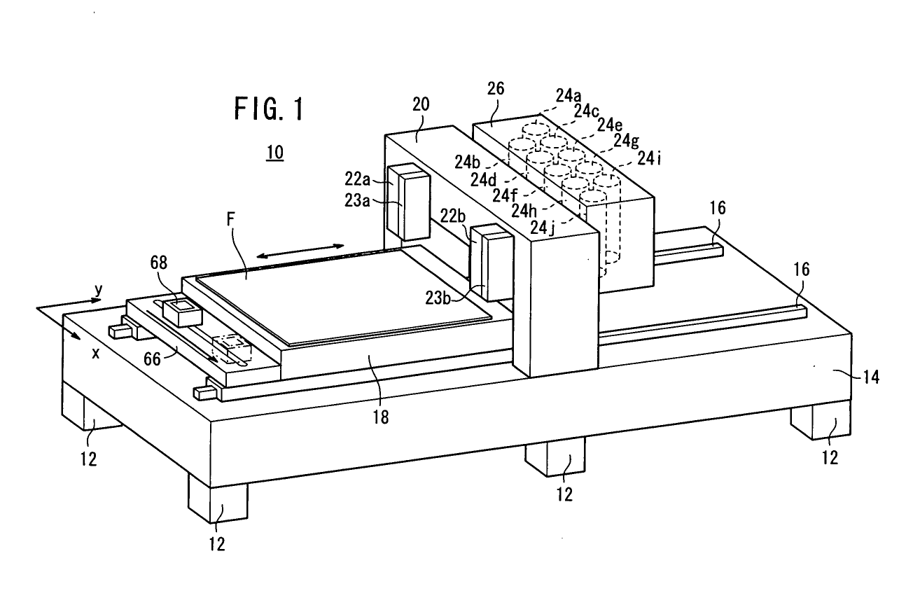

FIG. 1 shows in perspective an exposure apparatus 10 (digital exposure apparatus) according to an embodiment of the present invention. The exposure method according to the present invention is carried out utilizing the exposure apparatus 10.

As shown in FIG. 1, the exposure apparatus 10 includes a bed 14 supported by a plurality of legs 12, and an exposure stage 18 mounted on the bed 14 by two guide rails 16 enabling reciprocating movement in the directions indicated by the arrow. An elongate rectangular substrate (a substrate comprising a thin film coated with a resist) F, which comprises a thin film coated with a photosensitive resist material, is attracted to and held on the exposure stage 18.

A portal column 20 is mounted centrally on the bed 14 over the guide rails 16. Two CCD cameras 22a, 22b are fixed to one side of the column 20 for detecting the position at which the substrate F is mounted with respect to the exposure stage 18. Film thickness measuring sensors (film thickness measuring units) 23a, 23b also are fixed to the same side of the column 20 in order to measure the film thickness of the resist on the surface of the substrate F. A scanner 26, which includes a plurality of exposure heads 24a through 24J positioned and held therein for recording an image on the substrate F by way of exposure, is fixed to the other side of the column 20. The exposure heads 24a through 24J are arranged in two staggered rows in a direction perpendicular to the directions in which the substrate F is scanned (the directions of movement of the exposure stage 18).

Each of the film thickness measuring sensors 23a, 23b may comprise a known type of ellipsometer, for applying linearly polarized light to the surface of an object to be measured and measuring a change in the polarized state of light reflected from the object (i.e., a change from linearly polarized to elliptically polarized light) and then calculating the film thickness (and refractive index) of the resist. The film thickness measuring sensors 23a, 23b need not be integrally combined with the exposure apparatus 10, but may also be disposed separately from the exposure apparatus 10. The film thickness measuring sensors 23a, 23b may not necessarily comprise reflective spectral sensors, but may comprise optical interference sensors.

A guide table 66, which extends in a direction perpendicular to the direction of movement of the exposure stage 18, is mounted on an end of the bed 14. The guide table 66 supports a photosensor 68 thereon, which is movable in the direction indicated by the arrow X, for detecting an amount of light of light beams (laser beams) L that are emitted from the exposure heads 24a through 24j.

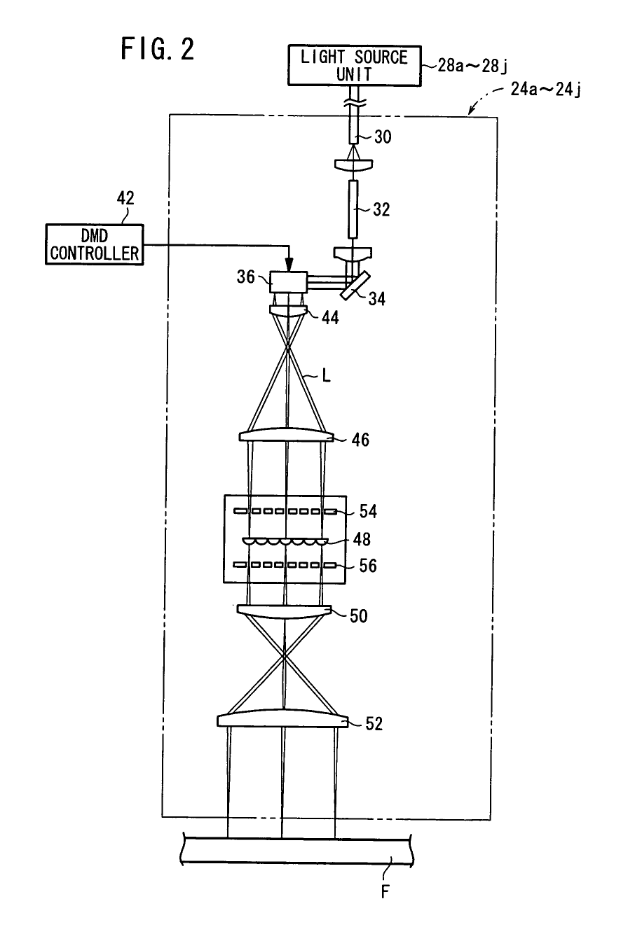

FIG. 2 shows the structure of each of the exposure heads 24a through 24j. A combined laser beam L, emitted from each of a plurality of semiconductor lasers making up light source units (illuminating system) 28a through 28f, is introduced through an optical fiber 30 into each of the exposure heads 24a through 24j. A rod lens 32, a reflecting mirror 34, and a digital micromirror device (DMD) 36 are successively arranged on the exiting end of the optical fiber 30 into which the laser beam L is introduced.

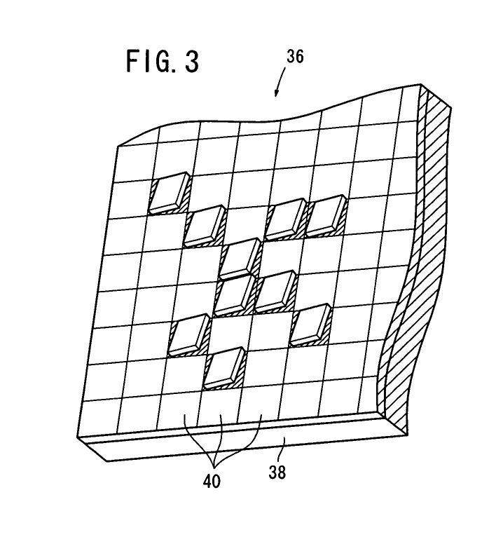

As shown in FIG. 3, the DMD 36 comprises a number of micromirrors (exposure recording elements) 40 that are swingably disposed in a matrix pattern on SRAM cells (memory cells) 38. A high reflectance material such as aluminum or the like is evaporated on the surface of each of the micromirrors 40. When a digital signal according to image plotting data is written into the SRAM cells 38 by a DMD controller 42, the micromirrors 40 are tilted in given directions depending on the applied digital signal. Depending on how the micromirrors 40 are tilted, the laser beam L is either turned on or off.

First image focusing optical lenses 44, 46 of a magnifying optical system, a microlens array 48 having many lenses corresponding to the respective micromirrors 40 of the DMD 36, and second image focusing optical lenses 50, 52 of a zooming optical system are disposed successively along a direction in which the laser beam L, which has been reflected by the DMD 36 while being controlled so as to be turned on or off, is emitted. Microaperture arrays 54, 56 for removing stray light and adjusting the laser beam L to a predetermined diameter are disposed in front of and behind the microlens array 48.

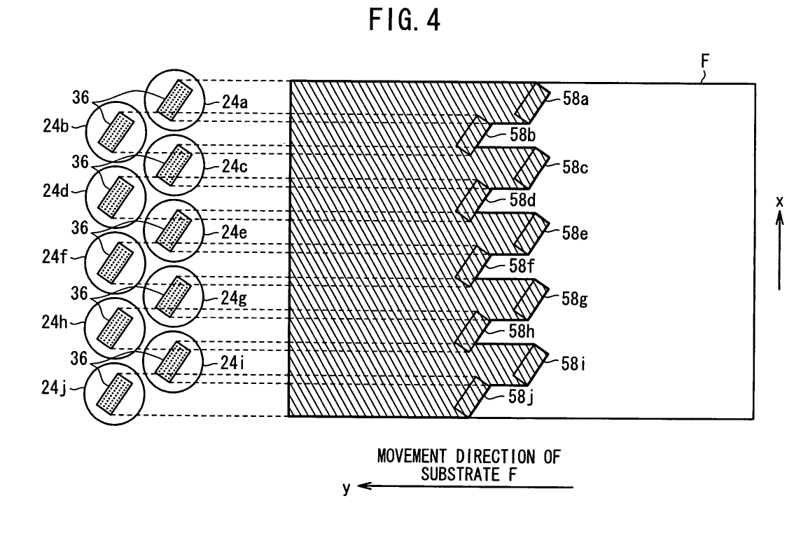

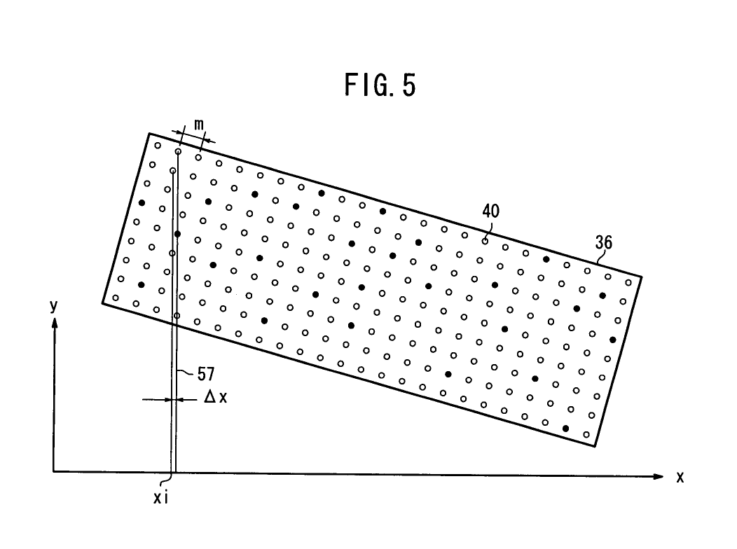

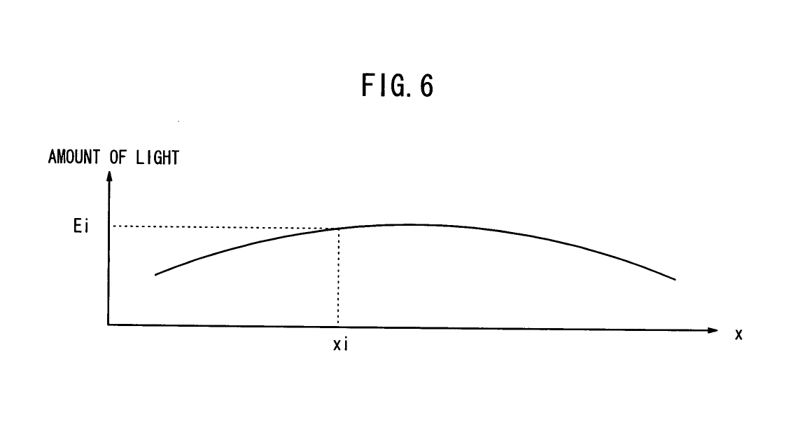

As shown in FIGS. 4 and 5, for achieving higher resolution, the DMDs 36 incorporated in the respective exposure heads 24a through 24j are inclined at a predetermined angle with respect to the movement direction of the exposure heads 24a through 24j. Specifically, the DMDs 36 inclined to the direction in which the substrate F is scanned (the direction indicated by the arrow Y) reduce the interval Δx between the micromirrors 40, in a direction (the direction indicated by the arrow X) perpendicular to the scanning direction of the substrate F, to a value smaller than the interval m between the micromirrors 40 of the DMDs 36 in a direction in which the micromirrors 40 are arrayed, thereby increasing resolution.

In FIG. 5, a plurality of micromirrors 40 are disposed along one scanning line 57 in the scanning direction (the direction indicated by the arrow Y) of the DMDs 36. The substrate F is exposed to multiple images of one pixel by laser beams L, which are guided substantially to the same position by the micromirrors 40. In this manner, amount-of-light irregularities between the micromirrors 40 can be averaged. In order to make the exposure heads 24a through 24j seamless, the exposure heads 24a through 24j are arranged such that exposure areas 58a through 58j thereof, which are exposed one at a time by the respective exposure heads 24a through 24j, overlap each other in the direction indicated by the arrow X.

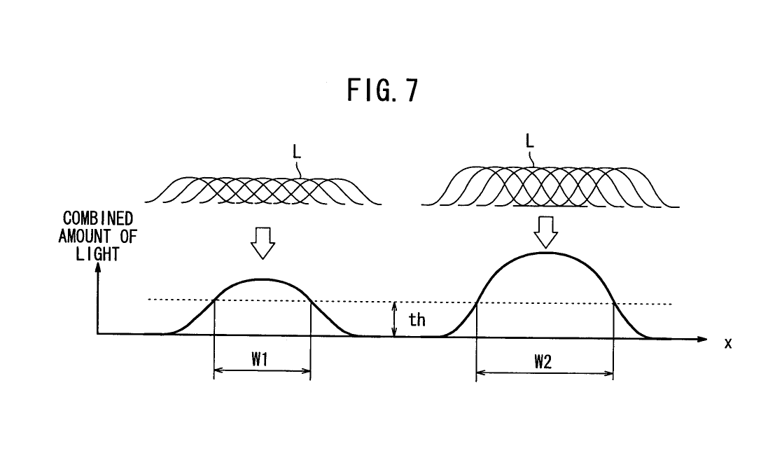

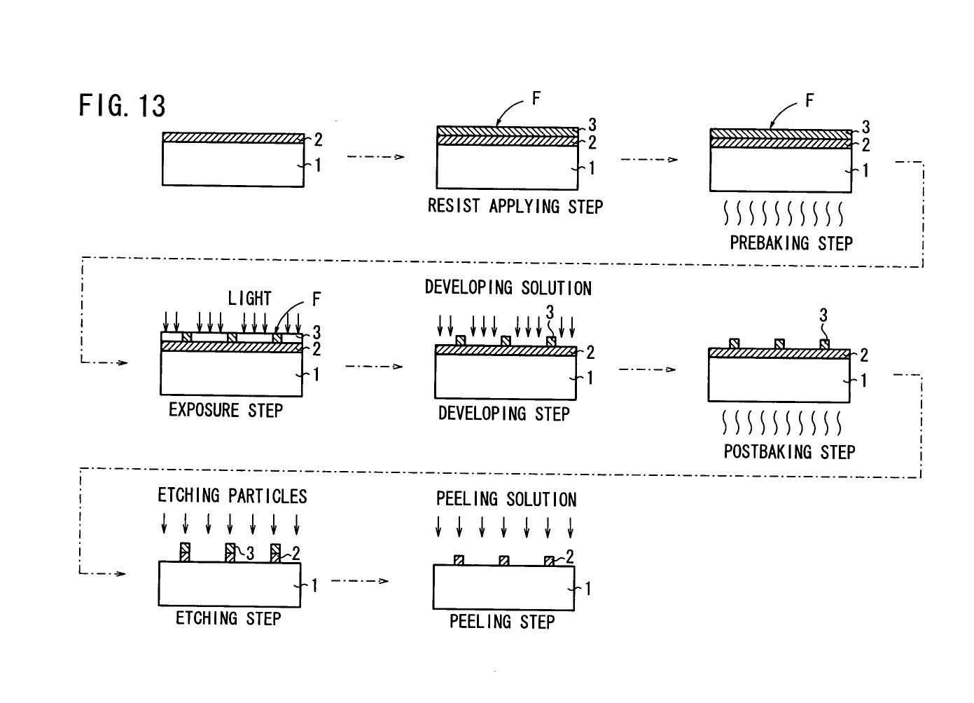

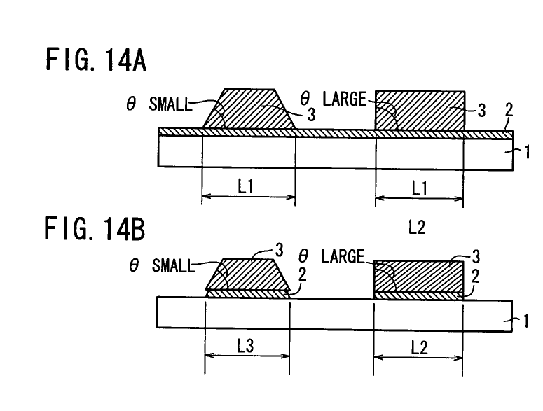

The amount of light of the laser beam L, which is guided to the substrate F by each of the micromirrors 40 of the DMDs 36, has a locality caused by the reflectance of the micromirrors 40 of the DMDs 36 along the direction indicated by the arrow X in which the exposure heads 24a through 24J are arrayed, as well as being caused by recording characteristics of the optical systems. With such a locality, as shown in FIG. 7, when an image is recorded on the substrate F by laser beams L reflected by a plurality of micromirrors 40 having a smaller combined amount of light, and when an image is recorded on the substrate F by laser beams L reflected by the micromirrors 40 having a greater combined amount of light, the images exhibit different widths W1, W2 respectively in the direction indicated by the arrow X, the widths being determined by a threshold th beyond which the photosensitive material applied to the substrate F is sensitive to the laser beams L. When the exposed substrate F is processed by a subsequent developing process, etching process, and peeling process, as shown in FIG. 13, the line widths (widths of the images) also are varied as a result of resist film thickness irregularities, developing process irregularities, etching process irregularities, and peeling process irregularities, as well as by the localities of the amount of light of the laser beams L.

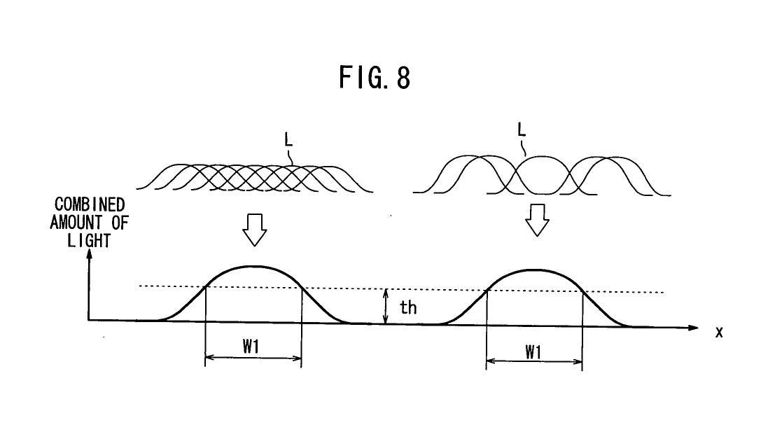

In view of the foregoing various factors responsible for variations, the number of micromirrors 40 used to form one pixel of an image on the substrate F is set and controlled using mask data (referred to as DMD mask data), so that, as shown in FIG. 8, the line width W1 is made constant in the direction indicated by the arrow X of the pattern, which is produced on the substrate F after the final pealing process, regardless of its position.

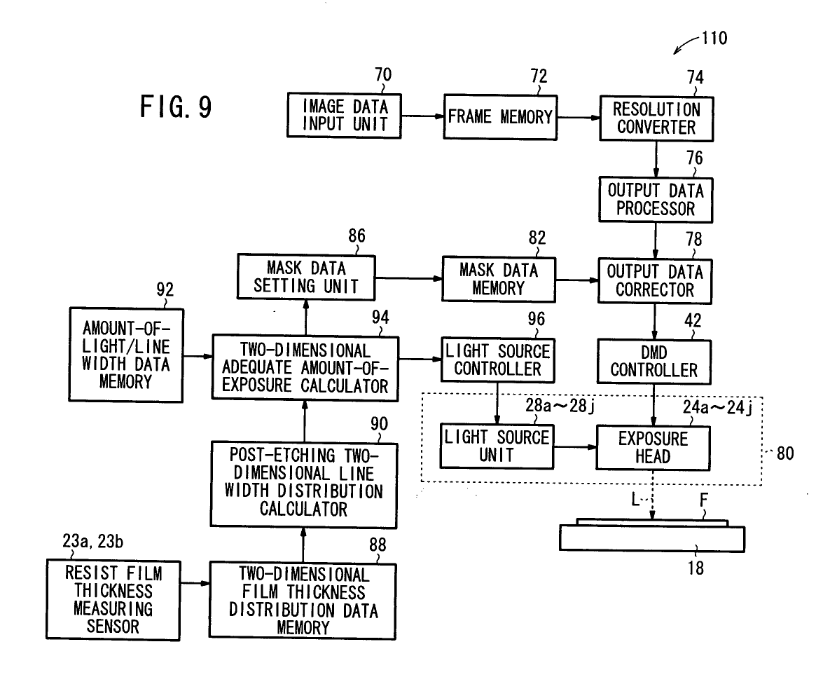

FIG. 9 shows in block form a control circuit 110 of the exposure apparatus 10, which functions to perform the above-described control process.

As shown in FIG. 9, the control circuit 110 comprises an image data input unit 70 for entering image data (raster data representing a matrix of pixels as an image) to be recorded on the substrate F by way of exposure, a frame memory 72 for storing the input two-dimensional image data, a resolution converter 74 for converting the resolution of the image data stored in the frame memory 72 into a higher resolution depending on the size and layout of the micromirrors 40 of the DMDs 36 of the exposure heads 24a through 24j, an output data processor 76 for processing the resolution-converted image data into output data (also referred to as mirror data or frame data, i.e., data for defining on and off states of the respective micromirrors 40 for exposing pixels at corresponding positions at the same timing) to be assigned to the micromirrors 40, an output data corrector 78 for correcting the output data according to mask data (data specifying certain micromirrors 40 among the micromirrors 40 to be turned off at all times for exposing pixels at corresponding positions at the same timing), a DMD controller 42 (exposure recording element control means) for controlling the DMDs 36 according to the corrected output data, and the exposure heads 24a through 24j, which record a desired image on the substrate F with the DMDs 36 that are controlled by the DMD controller 42. The light source units 28a through 28J and the exposure heads 24a through 24j jointly make up an exposure machine 80.

A mask data memory (DMD mask data memory) 82 (mask data storage means) for storing mask data is connected to the output data corrector 78. The mask data make up data for specifying which micromirrors 40 are to be turned off at all times during an exposure scanning process. The mask data are set by a mask data setting unit (DMD mask data setting unit) 86.

The control circuit 110 also has a two-dimensional film thickness distribution data memory 88 for storing resist film thicknesses (two-dimensional film thickness distribution) t (x, y), as detected by the film thickness measuring sensors 23a, 23b, at respective positions on the substrate F, which is to be exposed after the substrate F has been prebaked. The control circuit 110 also includes a post-etching two-dimensional line width distribution calculator (corrective line width amount determining means) 90 for calculating a corrective line width amount ΔL (x, y) according to a predetermined formula (first equation) with respect to a resist film thickness t (x, y) prior to exposure, and for calculating a post-etching line width (line width distribution) L (x, y). The control circuit 110 also includes a two-dimensional adequate amount-of-exposure calculator (amount-of-exposure correcting means) 94 for calculating an adequate amount of exposure Eex (x, y) at each two-dimensional position, including a corrected amount of exposure (average corrected amount of exposure) Eave for each of the light source units 28a through 28j corresponding to the exposure heads 24a through 24j, according to a table stored in an amount-of-light/line width table memory 92, or according to a predetermined formula (second equation) and the corrective line width amount ΔL (x, y). Finally, the control circuit 110 includes a light source controller 96 for setting exposure amounts for the exposure heads 24a through 24j in the respective light source units 28a through 28J. The two-dimensional adequate amount-of-exposure calculator 94 sets the corrected amount of exposure Eave in the light source units 28a through 28j for exposing the substrate F to an adequate amount of exposure Eex (x, y) through the light source controller 96, while also setting off states of the individual micromirrors 40 of the DMDs 36 of the exposure heads 24a through 24j in the DMD mask data setting unit 86.

A formula with respect to the resist film thickness t (x, y) prior to exposure and the post-etching line width (line width distribution) L (x, y) is represented by the following first equation:

L(x,y)=h(E/E0,θ) (1)

where E represents the exposure amount (exposure energy), E0 represents the resist sensitivity distribution (E0 (x, y)), and θ represents the taper angle.

A formula with respect to the exposure amount and line width is represented by the following second equation:

L=x(E) (2)

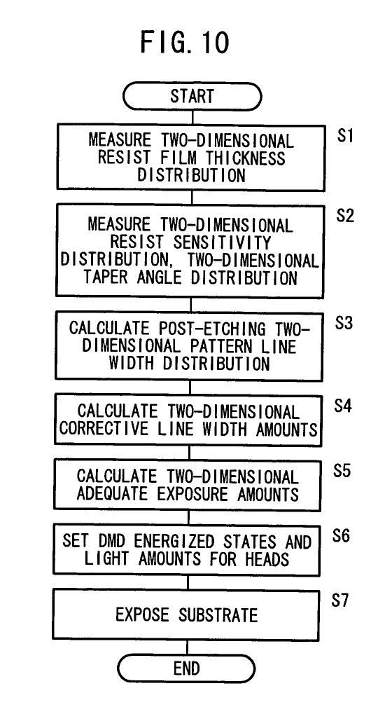

The exposure apparatus 10 according to the present embodiment is constructed basically as described above. A process for correcting a post-etching line width locality based on a resist film thickness locality by means of an exposure amount shall be described below with reference to the flowchart shown in FIG. 10.

As shown in FIG. 13, the substrate F, which includes a prebaked substrate 1 with the resist 3 applied to the thin film 2, is fixedly mounted on the exposure stage 18 of the exposure apparatus 10. In step S1, while the column 20 is displaced in the direction indicated by the arrow Y, the resist film thickness distribution in the two-dimensional plane of the substrate F, i.e., the resist film thickness t (x, y) at all respective positions on the substrate F, is measured by the film thickness measuring sensors 23a, 23b and stored in the two-dimensional film thickness distribution data memory 88.

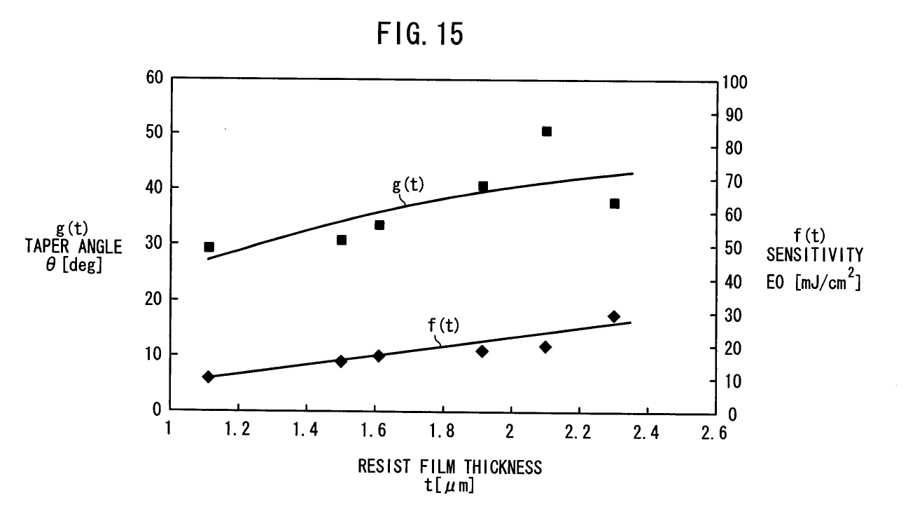

Then, in step S2, the post-etching two-dimensional line width distribution calculator 90 refers to the two relationships [the sensitivity E0=f(t), the taper angle θ=g(t)] shown in FIG. 15, which have been obtained experimentally in advance, and calculates two-dimensional sensitivities (two-dimensional sensitivity distribution: sensitivities at the respective positions on the substrate F) E0(x, y) and two-dimensional taper angles (two-dimensional taper angle distribution: taper angles θ at the respective positions on the substrate F)θ (x, y) from the measured resist film thicknesses t (x, y).

Then, in step S3, the post-etching two-dimensional line width distribution calculator 90 substitutes the two-dimensional sensitivities E0, the two-dimensional taper angles θ, and the exposure amount E in the first equation {L (x, y)=h (E/E0, θ)}, and calculates line widths (line width distribution) L (x, y) for the pattern of the etched thin film 2.

In step S4, the post-etching two-dimensional line width distribution calculator (corrective line width amount determining means) 90 determines corrective line width amounts (distribution) ΔL (x, y), representative of differences between the line widths L (x, y), and adequate line widths (designed light widths: desired line widths (distribution) of the thin film 2 to be achieved after the etching and pealing steps have been performed) Ld (x, y) at respective positions on the substrate F.

Thereafter, in step S5, the two-dimensional adequate amount-of-exposure calculator (amount-of-exposure correcting means) 94 calculates corrected exposure amounts ΔEave to be set in the exposure heads 24a through 24; through the light source units 28a through 28j, based on the corrective line width amounts ΔL (x, y) according to the second equation L=x (E), and calculates two-dimensional adequate exposure amounts Eex (x, y) for correcting the corrective line width amounts ΔL (x, y) at the respective positions.

Then, in step S6, in order to expose the substrate F to the two-dimensional adequate exposure amounts Eex (x, y), the light source controller 96 sets exposure amounts for the respective exposure heads 24a through 24j, while the DMD mask data setting unit 86 controls energization of the micromirrors 40 of the DMDs 36. The DMD mask data are set as data for determining which micromirrors, among the micromirrors 40, are to be turned off, for producing one pixel of an image at positions xi (i=1, 2, . . . ) on the substrate F.

After making the above corrective settings, the substrate F, including the thin film 2 coated with the resist 3, is exposed to a desired wiring pattern in step S6, as described below.

First, image data representing a desired wiring pattern are entered from image data input unit 70. Such entered image data are stored in the frame memory 72, and then supplied to the resolution converter 74. The resolution converter 74 converts the resolution of the image data into a given resolution depending on the resolution of the DMDs 36, and supplies the resolution-converted image data to the output data processor 76. Based on the resolution-converted image data, the output data processor 76 calculates output data representing signals for selectively turning on and off the micromirrors 40 of the DMDs 36. The calculated output data is supplied to the output data corrector 78.

The output data corrector 78 reads the mask data from the mask memory 82 and, by means of the mask data, corrects the on- and off-states of the micromirrors 40 represented by the output data. Then, the corrected output data is supplied to the DMD controller 42.

The DMD controller 42 energizes the DMDs 36 based on the corrected output data so as to selectively turn on and off the micromirrors 40. Laser beams L, which are output from the light source units 28a through 28j and introduced into the exposure heads 24a through 24j through the optical fiber 30, are applied to the DMDs 36 via the rod lenses 32 and the reflecting mirrors 34. Laser beams L that are selectively reflected in desired directions by the micromirrors 40 of the DMDs 36 are magnified by the first image focusing optical lenses 44, 46, and then adjusted to a predetermined beam diameter by the microaperture arrays 54, the microlens arrays 48, and the microaperture arrays 56. Thereafter, the laser beams L are adjusted to attain a predetermined magnification by the second image focusing optical lenses 50, 52 and guided to the substrate F. The exposure stage 18 moves along the bed 14, during which time a desired wiring pattern is recorded on the substrate F by the exposure heads 24a through 24j, which are arrayed in a direction perpendicular to the direction in which the exposure stage 18 moves.

After a desired wiring pattern has been recorded on the substrate F, the substrate F is removed from the exposure apparatus 10, whereupon a developing step, an etching step, and a peeling step are performed on the substrate F. The light amounts of the laser beams L applied to the substrate F are adjusted in view of all processes performed on the substrate F, including the final peeling step, based on the mask data and the corrected exposure amounts. Consequently, in step S6, it is possible to obtain a highly accurate wiring pattern having a desired uniform line width (distribution) L (x, y).

If the laser beams L are generated by a light-scanning digital exposure system comprising a light deflector such as a rotary polygon mirror, a galvanometer mirror, or the like, the intensities of the light sources may be modulated in step S6 in order to change the exposure intensities at the energized pixels, for thereby providing an adequate distribution in the exposure amounts Eex (x, y).

The above-described control circuit 110 shown in FIG. 9 is designed to perform a process for correcting post-etching line width localities based on resist film thickness localities, as indicated by the flowchart shown in FIG. 10.

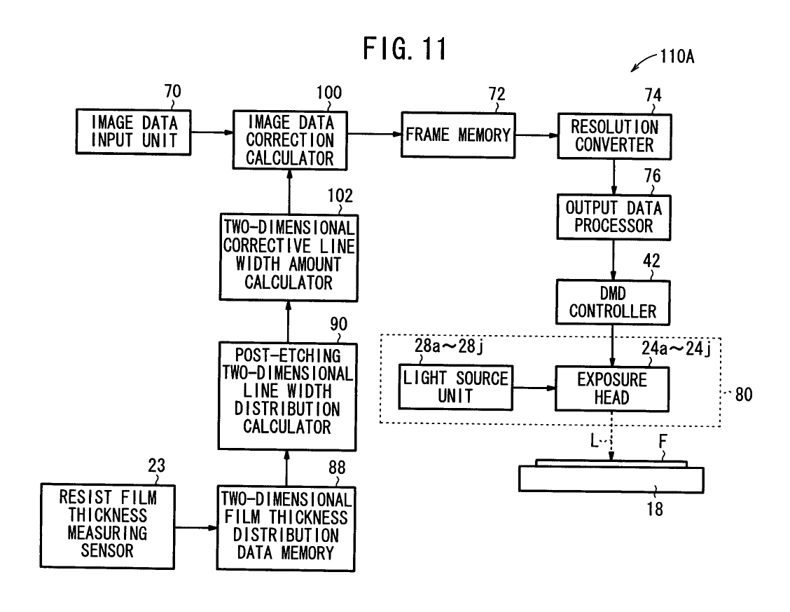

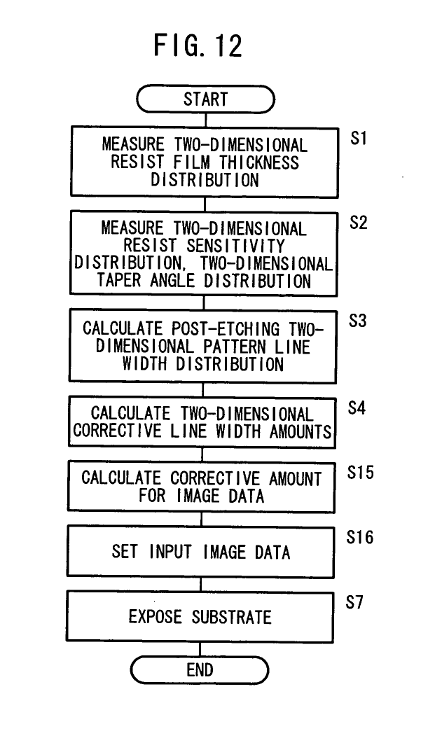

FIG. 11 shows in block form a control circuit 110A according to another embodiment of the present invention, which performs a process on the image data applied to the exposure machine 80, for correcting post-etching line width localities based on resist film thickness localities, as indicated by the flowchart shown in FIG. 12.

Parts shown in FIGS. 11 and 12 that are identical to or correspond with the same features shown in FIGS. 9 and 10 are denoted using identical reference characters, and such features shall not be described in detail below.

As shown in FIG. 11, the control circuit 110A includes an image data correction calculator (image data calculating means) 100 inserted between the image data input unit 70 and the frame memory 72. The image data correction processor 100 corrects the image data with an output signal from a two-dimensional corrective line width amount calculator (corrective line width amount determining means) 102, which is connected to the output of the post-etching two-dimensional line width distribution calculator 90. The output data corrector 78 (see FIG. 9) is not included in the control circuit 110A.

The flowchart shown in FIG. 12 includes steps S1 through S4 and step S7, which are identical to those steps shown in the flowchart of FIG. 10.

In step S15, the two-dimensional corrective line width amount calculator 102 calculates image data corrective amounts ΔG (x, y), which serve as corrective amounts (distributions) for increasing or reducing the line width, corresponding to the corrective line width amounts ΔL (x, y) at respective positions on the substrate F, which are supplied from the post-etching two-dimensional line width distribution calculator 90.

In step S16, the image data correction calculator (image data enlargement/reduction calculating means) 100 applies image data corrective amounts ΔG (x, y) to the image data supplied from the image data input unit 70, and stores the corrected (enlarged or reduced) image data in the frame memory 72.

After the above correction settings have been made, the substrate F including the thin film 2 coated with the resist 3 thereon is exposed to a desired wiring pattern in step S7, as described above. In this manner, a highly accurate pattern having the desired uniform line width (distribution) L (x, y) is produced on the substrate F.

In the exposure apparatus 10, 10A according to the above embodiments, the resist 3 applied to the thin film 2 on the substrate 1 is scanned and exposed by the exposure machine 80, which is turned on and off based on the image data. Thereafter, the resist 3 is developed and etched to produce a pattern having a desired line width from the thin film 2. Prior to exposure, the film thickness measuring sensors (film thickness measuring units) 23a, 23b measure a resist film thickness t (x, y) on the substrate F. Thereafter, the two-dimensional corrective line width amount calculator 102, or the post-etching two-dimensional line width distribution calculator (corrective line width amount determining means) 90, determines a corrective etching line width amount ΔL (x, y) for the measured resist film thickness t (x, y), based on a predetermined relationship between the pre-exposure resist film thickness t (x, y) and the post-etching corrective line width amount ΔL (x, y). Based on the determined corrective line width amount ΔL (x, y), the image data correction calculator 100, or alternatively the DMD mask data setting unit (amount-of-exposure correcting means) 86, corrects the exposure amount set in the exposure machine 80 so as to achieve a desired line width. Accordingly, the amount of exposure set in the exposure machine 80 in order to achieve a desired line width can be corrected according to a simple process.

As a result, post-etching line width localities that occur due to resist film thickness localities can be corrected continuously, without the need for an expensive mask as required in the related art. If the present invention is applied to an LCD (Liquid Crystal Display) serving as a flat panel display or FPD, then illuminance irregularities in the LCD can be reduced.

The corrective line width amount ΔL (x, y) is corrected by the exposure amount at each position on the substrate F. Therefore, in the control circuit 110 shown in FIG. 9, the exposure heads 24a through 24j are controlled by the light source controller 96 and the light source units 28a through 28j based on an average corrected exposure amount ΔE, whereby certain micromirrors 40 of the exposure heads 24a through 24j are turned off by the DMD mask data setting unit 86, the DMD mask data memory 82, and the output data corrector 78, in order to correct the exposure amount.

By the control circuit 110A shown in FIG. 11, within the image data, the corrective line width amount ΔL (x, y) may be corrected by the image data correction calculator 100. Generally, the image data can be corrected more easily than if the light beam intensities emitted from the light source units 28a through 28f were modulated.

According to the embodiments of the present invention, post-etching line width localities that occur due to resist film thickness localities can be corrected.

Although certain preferred embodiments of the present invention have been shown and described in detail, it should be understood that various changes and modifications may be made to such embodiments without departing from the scope of the invention as set forth in the appended claims.

What is claimed is:

1. An exposure method to be performed by an exposure apparatus, for scanning and exposing a resist applied to a thin film on a substrate utilizing an exposure machine that is selectively turned on and off by image data, and thereafter developing and etching the resist and the thin film so as to produce a pattern having a desired line width in the thin film, said exposure method comprising the steps of:
measuring a pre-exposure film thickness of the resist on the substrate;
determining a corrective etching line width amount for the measured pre-exposure film thickness of the resist, based on a predetermined relationship between the pre-exposure film thickness of the resist and the post-etching corrective line width; and
correcting the pattern so as to achieve said desired line width, based on the determined post-etching corrective line width amount.

2. An exposure method according to claim 1, wherein said step of correcting the pattern comprises a step of correcting an amount of exposure set in said exposure machine, depending on a location on said substrate.

3. An exposure method according to claim 2, wherein said exposure machine comprises an exposure head having a plurality of exposure recording elements therein, wherein the exposure amount set in said exposure machine is corrected by turning off selected ones of said exposure recording elements.

4. An exposure method according to claim 3, wherein said exposure machine comprises a plurality of said exposure heads.

5. An exposure method according to claim 3, wherein said exposure machine comprises a digital micromirror device that includes said exposure recording elements, and an illuminating system for applying illuminating light to said digital micromirror device.

6. An exposure method according to claim 2, said exposure machine comprising a light deflector, wherein said step of correcting the exposure amount set in said exposure machine further comprises a step of correcting an intensity of a light beam, which is deflected by said light deflector depending on the location on said substrate.

7. An exposure method according to claim 1, wherein said step of correcting the pattern further comprises a step of correcting said image data depending on a location on said substrate, so as to correct an exposure amount set in said exposure machine.

8. An exposure method according to claim 7, wherein said step of correcting said image data further comprises a step of enlarging or reducing the line width, depending on the location on said substrate.

9. An exposure apparatus for scanning and exposing a resist applied to a thin film on a substrate utilizing an exposure machine that is selectively turned on and off by image data, and thereafter developing and etching the resist and the thin film so as to produce a pattern having a desired line width in the thin film, said exposure apparatus comprising:
a film thickness measuring unit for measuring a pre-exposure film thickness of the resist on the substrate;
corrective line width amount determining means for determining a corrective etching line width amount for the measured pre-exposure film thickness of the resist, based on a predetermined relationship between the pre-exposure film thickness of the resist and the post-etching corrective line width; and
amount-of-exposure correcting means for correcting an amount of exposure set in said exposure machine so as to achieve said desired line width, based on the determined post-etching corrective line width amount.
